(19) United States
(12) Patent Application Publication
(10) Pub. No.: US 2025/0275085 A1
(43) Pub. Date: Aug. 28, 2025

(54) PASSIVE COOLING APPARATUS FOR COOLING OF IMMERSION FLUID AND POWER CONVERSION EQUIPMENT AND RELATED SYSTEMS

(71) Applicant: Eaton Intelligent Power Limited, Dublin 4 (IE)

(72) Inventors: Avadhoot Kittur, Pune (IN); Shivayogi Salutagi, Pune (IN); Manoj Kumars Verma, Pune (IN); Donald Caulfield, Raleigh, NC (US); Rajiv Dalal, Mooresville, NC (US)

(21) Appl. No.: 18/865,743

(22) PCT Filed: Jun. 13, 2023
(86) PCT No.: PCT/EP2023/025281

§ 371 Date: Nov. 14, 2024

(30) Foreign Application Priority Data
Jun. 13, 2022 (IN) 202211033622

(51) Int. Cl. H05K 7/20

(52) U.S. Cl. CPC H05K 7/20236; H05K 7/20263; H05K 7/20272; H05K 7/20409; H05K 7/20927

(57) ABSTRACT

A passive fluid cooling system is provided including an immersion cooling tank including a volume of fluid and a plurality of fluid cooling channels attached to exterior sidewalls of the immersion cooling tank. The flow of the fluid through the plurality of fluid cooling channels positioned on the exterior sidewalls of the immersion cooling tank removes heat from the volume of fluid.

### CLAIM OF PRIORITY

The present application claims the benefit of and priority to Indian Provisional Application No. 20/221,1033622, filed on Jun. 13, 2022, entitled Passive Cooling Apparatus for Cooling of Immersion Fluid and Power Conversion Equipment and Related Systems, the content of which is hereby incorporated herein by reference as if set forth in its entirety.

### FIELD

The present inventive concept relates generally to immersion fluid and, more particularly, to the cooling of immersion fluid.

### BACKGROUND

The most common method for cooling information technology (IT) equipment, for example, equipment in data centers, power conversion equipment and the like is forced air. Using air as the coolant generally requires, for example, fans, ductwork, heating ventilation and air conditioning (HVAC) systems etc., which may consume a lot of space and electricity and generally add a cost.

An alternative to using air to cool the equipment, is immersion cooling, which is more energy and space efficient. Immersion cooling involves immersing system components in a fluid which, ideally, has a high coefficient of heat absorption and a low thermal resistance. In other words, the process generally requires the use of fluids that will not damage the IT components or degrade system function. Furthermore, for safety reasons, these fluids need to be “dielectric,” meaning they do not conduct electricity. The dielectric fluids used for immersion cooling today generally fall into two categories: oils (synthetic, mineral, bio) and engineered fluids.

Methods of immersion cooling involve immersing components and/or equipment in a dielectric fluid. The heat generated by the IT components is absorbed by the fluid and then the fluid is pumped and circulated around inside an enclosure, chassis or tank to help remove the heat. This entails pumping out the hot oil/fluid to be cooled by a secondary air-to-liquid or liquid-to-liquid heat exchanger and pumping cooled oil/fluid back into the immersion bath. Some methods include an entirely enclosed IT chassis that contains the dielectric fluid and oftentimes less fluid is needed as a result. Some methods include an entirely enclosed IT tank/immersion tank. The tanks provide containment of the dielectric fluid and are typically designed to accommodate IT components that would otherwise be mounted in racks. Since the immersion tanks accommodate almost all types of IT components, there is no need to replace the immersion tank for an IT refresh. This makes the flexibility and cost highly appealing for immersion tank versus the chassis approach. Although immersion cooling is available, improvements are needed.

### SUMMARY

Some embodiments of the present inventive concept provide a passive fluid cooling system including an immersion cooling tank including a volume of fluid and a plurality of fluid cooling channels attached to exterior sidewalls of the immersion cooling tank. The flow of the fluid through the plurality of fluid cooling channels positioned on the exterior sidewalls of the immersion cooling tank removes heat from the volume of fluid.

In further embodiments, the plurality of fluid cooling channels may be attached to the immersion cooling tank at first and second portions of the immersion cooling tank. As a temperature of the fluid in the immersion cooling tank increases, a density of the fluid decreases causing less dense fluid to rise to a top of the immersion cooling tank and flow into the plurality of fluid cooling channels cooling the fluid and flow back into the immersion cooling tank at a bottom portion of the immersion cooling tank.

In still further embodiments, the flow of the fluid through the plurality of fluid cooling channels decreases the temperature of the fluid providing a cooled fluid.

In some embodiments, the immersion cooling tank may further include electronic components positioned in the immersion cooling tank and the cooled fluid may cool the electronic components positioned in the immersion cooling tank.

In further embodiments, the flow of the fluid through the plurality of cooling channels may be induced without use of fans and/or pumps such that efficiency of power usage is increased.

In still further embodiments, the plurality of fluid cooling channels may have one of a finned shape, a radial disc shape, a fractal design, a rectangular shape, a racetrack shape, a round shape, a flat channel shape and combinations thereof.

In some embodiments, the fluid may be thermally conductive and electrically insulating.

In further embodiments, the fluid may have electrically insulating properties to ensure that the fluid can safely contact energized electronic components.

In still further embodiments, the fluid does not damage electronic components.

Passive cooling apparatus and immersion cooling tanks are also provided.

### BRIEF DESCRIPTION OF THE DRAWINGS

FIG. 1A is diagram illustrating an immersion tank including a plurality of fluid cooling channels in accordance with some embodiments of the present inventive concept.

FIG. 1B is a diagram illustrating one of the plurality of cooling channels (fins) in accordance with some embodiments of the present inventive concept.

FIG. 2A is a cross-section illustrating an immersion tank including components and coolant and having fins in accordance with some embodiments of the present inventive concept.

FIG. 2B is a perspective view of the system of FIG. 2A illustrating a three dimensional representation of the tank and the elements therein in accordance with some embodiments of the present inventive concept.

FIGS. 3A through 3C are diagrams illustrating a velocity contour diagram, a temperature contour diagram and a velocity vectors diagram, respectively, illustrating aspects of cooling using immersion fluid in accordance with some embodiments of the present inventive concept.

FIG. 4A is a diagram illustrating an immersion tank having hollow channel fluid cooling channels in accordance with some embodiments of the present inventive concept.

FIG. 4B is a cross section of the immersion tank having hallow channels illustrated in FIG. 4A in accordance with some embodiments of the present inventive concept.

FIG. 4C is a perspective view of the cross section of FIG. 4B showing three dimensions of the tank and the elements therein in accordance with some embodiments of the present inventive concept.

FIGS. 5A through 5C are diagrams illustrating a velocity contour diagram, a temperature contour diagram and a velocity vectors diagram, respectively, for embodiments illustrated in FIGS. 4A through 4C in accordance with some embodiments of the present inventive concept.

FIGS. 6A and 6B are diagrams illustrating flat external channels having connecting fins in accordance with some embodiments of the present inventive concept.

### DETAILED DESCRIPTION OF EMBODIMENTS

The inventive concept now will be described more fully hereinafter with reference to the accompanying drawings, in which illustrative embodiments of the inventive concept are shown. This inventive concept may, however, be embodied in many different forms and should not be construed as limited to the embodiments set forth herein; rather, these embodiments are provided so that this disclosure will be thorough and complete, and will fully convey the scope of the inventive concept to those skilled in the art. Like numbers refer to like elements throughout. As used herein, the term “and/or” includes any and all combinations of one or more of the associated listed items. Similarly, as used herein, the word “or” is intended to cover inclusive and exclusive OR conditions. In other words, A or B or C includes any or all of the following alternative combinations as appropriate for a particular usage: A alone; B alone; C alone; A and B only; A and C only; B and C only; and A and B and C.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Reference will now be made in detail in various and alternative example embodiments and to the accompanying figures. Each example embodiment is provided by way of explanation, and not as a limitation. It will be apparent to those skilled in the art that modifications and variations can be made without departing from the scope or spirit of the disclosure and claims. For instance, features illustrated or described as part of one embodiment may be used in connection with another embodiment to yield a still further embodiment. Thus, it is intended that the present disclosure includes modifications and variations that come within the scope of the appended claims and their equivalents.

As discussed above, power conversion equipment and electronic assemblies are often conventionally cooled using fan cooling, which uses forced air delivered by fans to a heat sink to dissipate heat generated by the components. More recently, immersion cooled electronic installations use active elements to cool the fluid, and thereby, the immersed electronics. The immersion fluid is generally pumped through the immersion container, then to a heat exchanger to remove the heat from the fluid. However, the fluid must be pumped around and a heat exchanger must be used to remove the heat from the liquid.

Accordingly, some embodiments of the present inventive concept provide a passive fluid cooling apparatus, which cools the immersion fluid without the need for extra equipment such as a heat exchanger. As will be discussed below, embodiments of the present inventive concept take advantage of the fact that when the temperature of the fluid, for example, a dielectric, in the tank increases, the density of the fluid decreases. Thus, the heated fluid rises to the top of the tank and is cooled by circulating the fluid through external tubes (fluid cooling channels). This external arrangement of tubes allows dissipation of heat without use of any fans or pumps which significantly increases power usage effectiveness and efficiency of the immersed electronic assemblies as will be discussed below with respect to the figures.

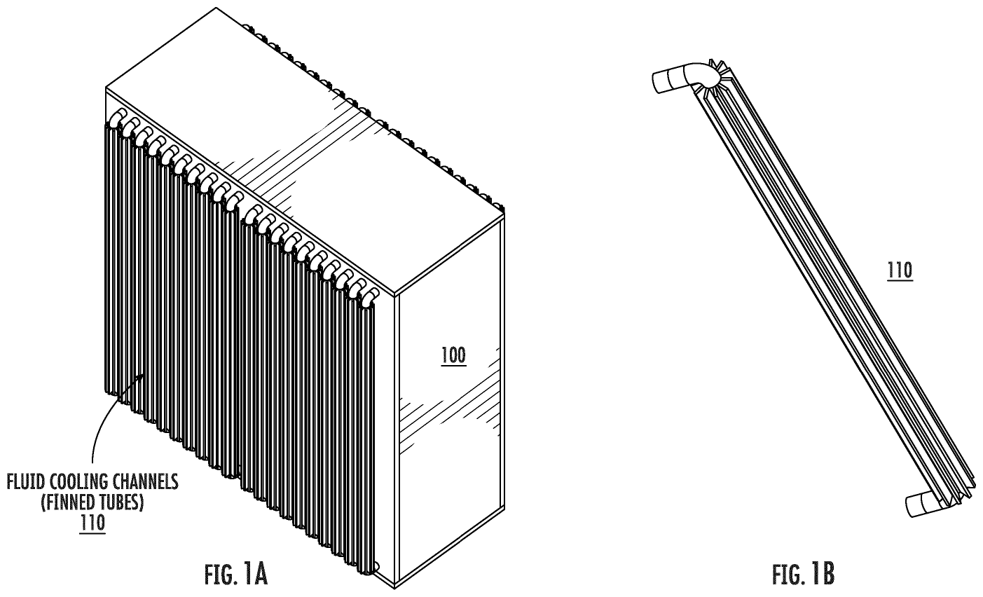

Referring first to FIGS. 1A and 1B, an immersion tank 100 and a plurality of fluid cooling channels 110 in accordance with some embodiments of the present inventive concept will be discussed. As illustrated in FIG. 1A, an immersion tank 100 is provided with a plurality of fluid cooling channels 110 attached to exterior sidewalls thereof. As used herein, “immersion cooling” is an information technology (IT) cooling practice by which IT components and other electronics, including complete servers and storage devices and power equipment, are submerged in a thermally conductive but electrically insulating dielectric liquid or coolant. Conventionally heat is removed from the system by circulating relatively cold liquid into direct contact with hot components, then circulating the now heated liquid through cool heat exchangers. Unlike many other applications, water cooling cannot be used as normal water is electrically conductive and will break electronic components. Fluids suitable for immersion cooling have electrically insulating properties to ensure that they can safely come into contact with energized electronic components.

An immersion cooling tank 100 is a tank in which the electronic components are placed and is filled with a body of dielectric liquid where electronic components are immersed in the dielectric liquid. Thus, various electronic components can share the same liquid. As used herein, the liquid or fluid can include any liquid, fluid, oil or the like that can be safely used to cool electronic equipment. The immersion cooling tanks is fully sealed and can generally be opened from the top to service the IT equipment therein.

Unlike conventional immersion cooling systems, embodiments of the present inventive concept include one or more fluid cooling channels 110 attached to the immersion cooling tank 100 that allows the fluid in the immersion cooling tank 100 to be circulated such that the fluid is cooled. Embodiments of a finned tube (fluid cooling channel) 110 in accordance with some embodiments of the present inventive concept is illustrated, for example, in FIG. 1B. As illustrated therein, the tube 110 is provided with a plurality of fins attached to the exterior thereof. Embodiments are not limited to the specific number of fins shown FIGS. 1A and 1B. The external arrangement of the tubes 110 on the tank 100 allows dissipation of heat from the liquid without use of any fans or pumps which significantly increases power usage effectiveness and efficiency of the immersed electronic assemblies.

In particular, as illustrated in FIGS. 1A and 1B, the tubes 110 attach at both the top and bottom of the tank 100 such that fluid flows from the tank 100 into the tubes 110 at the top portion of the tank 100 and fluid flows back into the tank 100 at the bottom of the tank. When a temperature of the fluid inside the tank, for example, a dielectric, increases, the density of the fluid decreases causing the less dense fluid to rise to the top of the tank 100. The fluid at the top of the tank 100 is filtered/circulated through the tubes 110 from the top of the tank 100 and reenters to the tank 100 at the bottom. The movement of the fluid through the external tubes 110 decreases the temperature of the fluid so that the fluid continues to cool the components positioned in the tank.

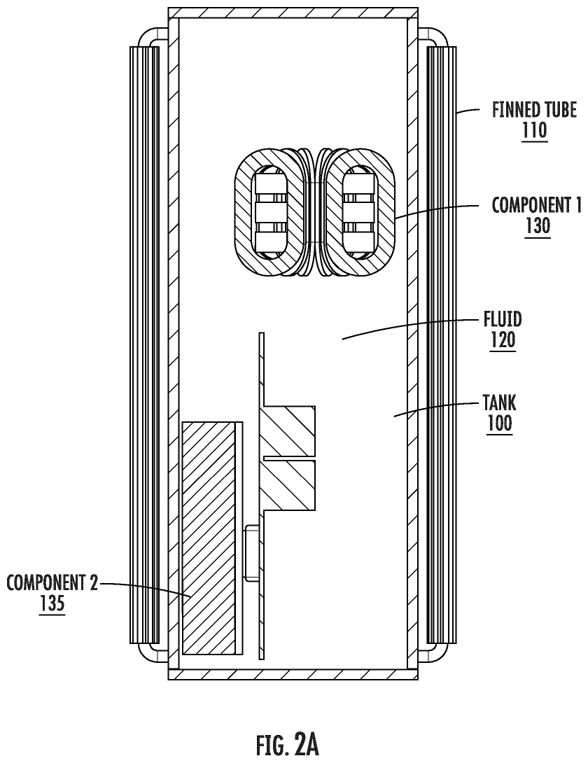

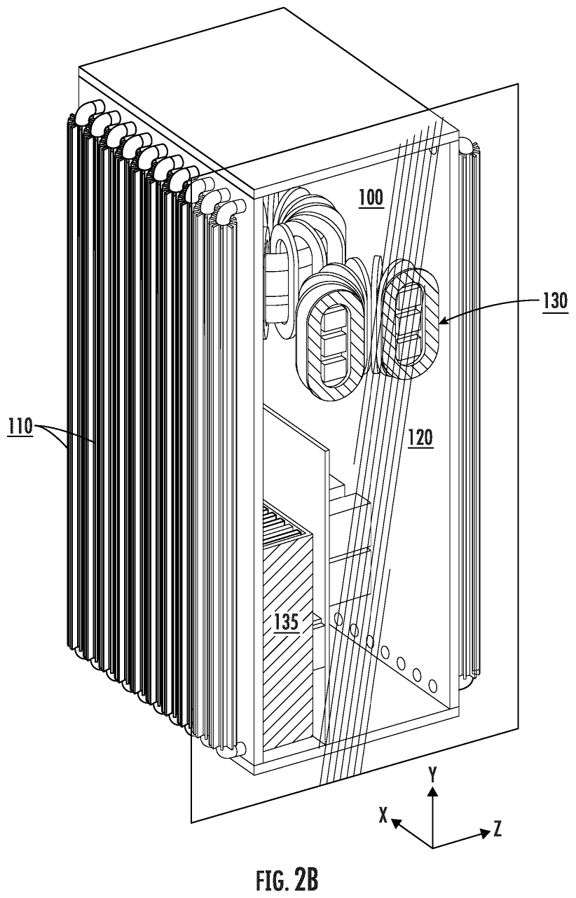

Referring now to FIGS. 2A, as illustrated in the cross-section of the tank 100, component(s) 130 and 135 are submerged in a coolant/fluid 120, for example, a dielectric liquid. As used herein, “components” refer to any electrical components that may generate heat that are customarily cooled in a traditional manner. For example, components discussed herein may include uninterruptable power supplies (UPSs), for example, single and three phase UPSs, motor drives, or any other power conversion equipment. Although FIG. 2A only illustrates two components 130 and 135 in the tank 100, embodiments of the present inventive concept are not limited to this configuration. A single component or more than two components may be positioned in the tank 100 without departing from the scope of the present inventive concept.

The heat associated with the component(s) 130 and 135 is transferred to the surrounding dielectric liquid (coolant 120). The temperatures used in immersion cooling are determined by the highest temperature at which the devices being immersed can reliably operate. For servers this temperature may range between 15 to 65° C. (59 to 149° F.), but may be extended up to 75° C. The transfer of heat to the coolant increases a temperature of coolant 120 near the component(s) 120, which results in a decrease in density of the coolant 120. The coolant 120 rises due to the resulting buoyancy force. The coolant 120 rising in the tank induces a circulating flow through the external tubes 110. The heat in the fluid is transferred to the surrounding air aided by the fins (FIG. 1B) which serve to increase the area available for heat transfer.

FIG. 2B is a perspective view of the cross section of the tank 100 of FIG. 2A. FIG. 2B illustrates x, y and z dimensions of the tank 100. Thus, the positioning of the components and other elements are more accurately depicted.

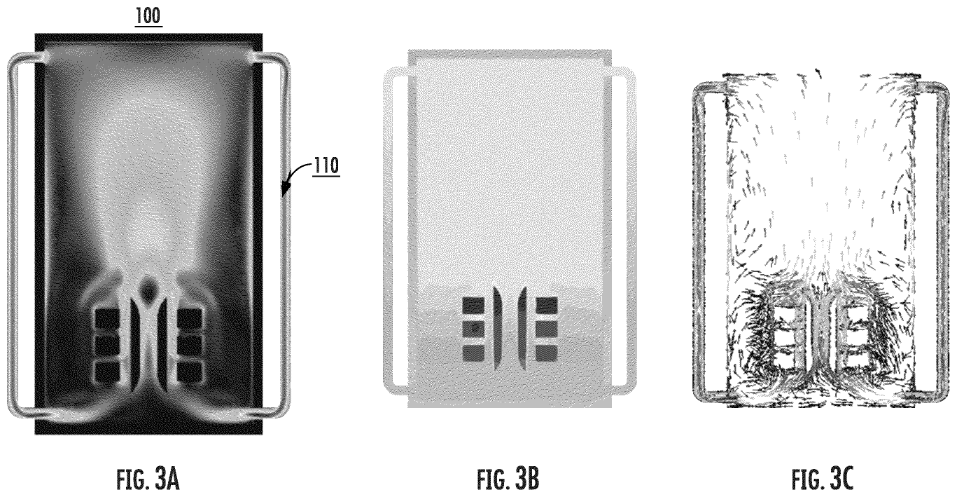

FIGS. 3A through 3C are a velocity contour diagram, a temperature contour diagram and a velocity vectors diagram, respectively, illustrating aspects of the present inventive concept. The vectors of FIG. 3C illustrate the induced circulating flow within the tank and through the tubes.

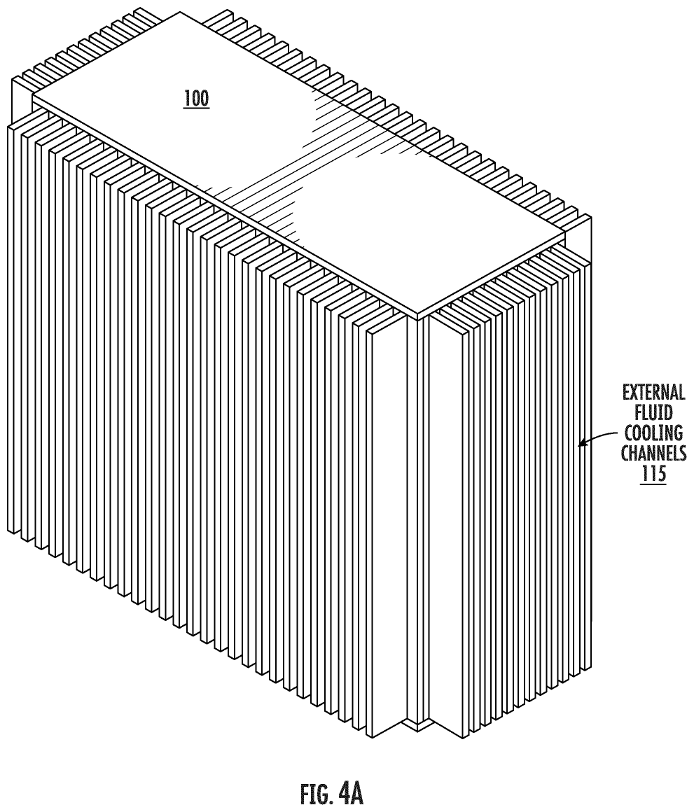

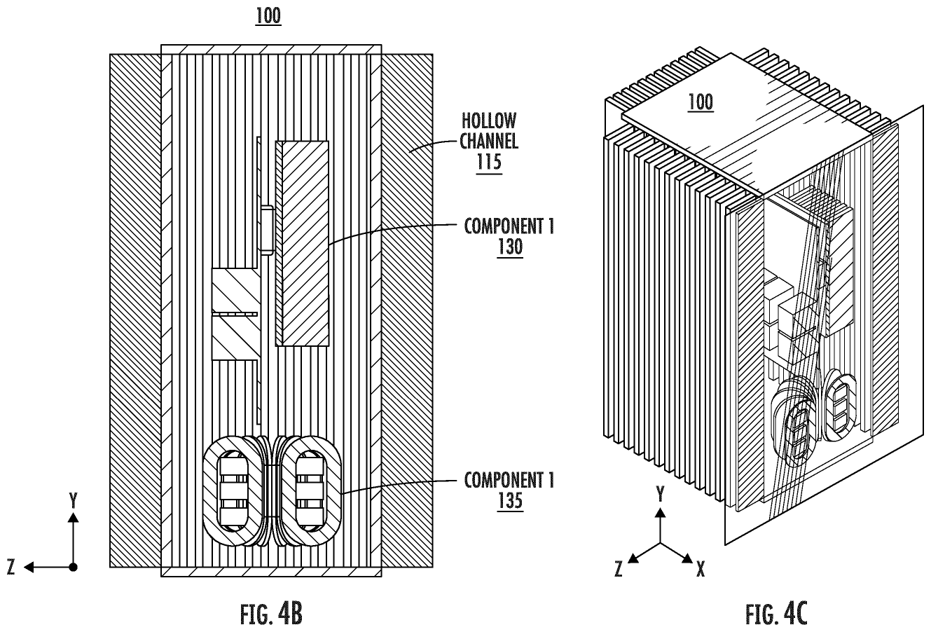

Although the fluid cooling channels 110 are shown having a finned configuration in FIGS. 1A through 2B, embodiments of the present inventive concept are not limited to this configuration. For example, any type or shape may be used for the fluid cooling channels without departing from the scope of the present inventive concept. Thus, any embodiment where one or more cooling channels are attached to an immersion tank may be used. The fluid cooling channels may be, for example, radial discs with holes, fractal designs, and the like. Furthermore, fluid cooling channels can have one or a combination of several cross-sections: round, rectangular, racetrack, etc. Examples of various embodiments of fluid cooling channels are illustrated in FIGS. 4A through 4C. Embodiments are not limited to those shown in these figures and these figures are provided for example only.

Referring in particular to FIGS. 4A through 4C illustrating hollow channel embodiments for the fluid cooling channel in accordance with some embodiments of the present inventive concept. FIG. 4A As illustrated in FIG. 4A, external flat channels 115 are formed into or attached to the side of tank 100. In these embodiments, passages inside the flat channels 156 conduct the fluid to exhaust the heat to the surrounding air. The circulatory flow in the tank 100 and external channels 115 is the same or similar as in the tank and tubes as discussed above.

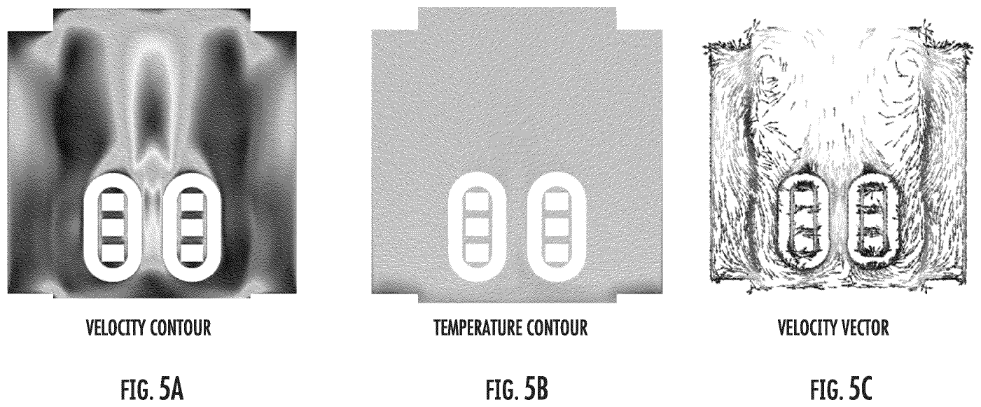

FIGS. 5A through 5C are diagrams illustrating a velocity contour diagram, a temperature contour diagram and a velocity vectors diagram, respectively, for embodiments illustrated in FIGS. 4A through 4C in accordance with some embodiments of the present inventive concept.

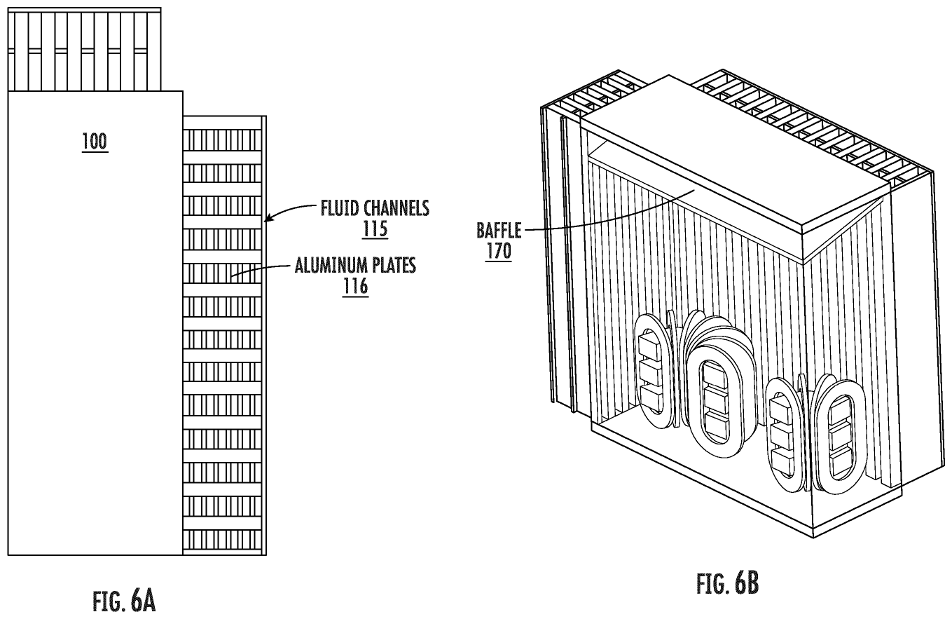

FIGS. 6A and 6B are a diagram and perspective cross section, respectively, of embodiments including flat channels and connections fins. As illustrated in FIG. 6A, the flat channels 115 have interconnecting fins 116 (aluminum plates) to increase surface area in order to augment heat transfer as shown in FIGS. 3A-3C and FIGS. 5A through 5C. Furthermore, FIG. 6B illustrates a baffle 170 for replacing fluid or removing/adding components.

In some embodiments, the tank itself may be made to include features that guide the less dense fluid into the fluid cooling channels as discussed herein. For example, in some embodiments, a portion of the top of the tank may angle downward to facilitate entry of the fluid into the fluid cooling channels. Furthermore, additional features, such as baffles, can be installed inside the tank 100 to help direct the flow of the heated coolant 120 to augment effectiveness of the tank 100. These baffles can be an integral part of the tank 100 structure or installed separately. These baffles can be custom configured depending on what components or equipment are being cooled. The installed equipment can also have individual features that assist in directing the coolant 120 to increased cooling effectiveness.

As discussed above, conventional immersion cooled electronic installations use active elements to cool the fluid, and thereby, the immersed electronics. The immersion fluid is generally pumped through the immersion container (tank), then to a heat exchanger to remove the heat from the fluid. Embodiments of the present inventive concept provide a passive fluid cooling apparatus which reduces the power consumption of immersion cooled equipment and expands possible installation location options for the IT equipment.

In particular, immersion cooling reduces energy consumption through the elimination of the air cooling infrastructure including on-board server fans, CRACs, A/C compressors, air-circulation fans, necessary duct work, air handlers, and other active ancillary systems such as dehumidifiers. As discussed above, embodiments of the present inventive concept replace these conventional systems with liquid immersion techniques having passive cooling systems for the fluid in the tanks. Thus, embodiments of the present inventive concept do not require fans to circulate the dielectric liquid nor heat exchangers to cool the liquid.

It should be emphasized that the above-described embodiments of the present disclosure are merely possible examples of implementations set forth for a clear understanding of the principles of the disclosure. It is, of course, not possible to describe every conceivable combination of components and/or methodologies, but one of ordinary skill in the art may recognize that many further combinations and permutations are possible. That is, many variations and modifications may be made to the above-described embodiment(s) without departing substantially from the spirit and principles of the disclosure. All such modifications and variations are intended to be included herein within the scope of this disclosure and protected by the following claims.

That which is claimed is:

1. A passive fluid cooling system, comprising:
an immersion cooling tank including a volume of fluid; and
a plurality of fluid cooling channels attached to exterior sidewalls of the immersion cooling tank, wherein flow of the fluid through the plurality of fluid cooling channels positioned on the exterior sidewalls of the immersion cooling tank removes heat from the volume of fluid.

2. The passive fluid cooling system of claim 1, wherein the plurality of fluid cooling channels are attached to the immersion cooling tank at first and second portions of the immersion cooling tank, wherein as a temperature of the fluid in the immersion cooling tank increases, a density of the fluid decreases causing less dense fluid to rise to a top of the immersion cooling tank and flow into the plurality of fluid cooling channels cooling the fluid and flow back into the immersion cooling tank at a bottom portion of the immersion cooling tank.

3. The passive fluid cooling system of claim 2, wherein the flow of the fluid through the plurality of fluid cooling channels decreases the temperature of the fluid providing a cooled fluid.

4. The passive fluid cooling system of claim 3, wherein the immersion cooling tank further includes electronic components positioned in the immersion cooling tank and wherein the cooled fluid cools the electronic components positioned in the immersion cooling tank.

5. The passive fluid cooling system of claim 1, wherein the flow of the fluid through the plurality of cooling channels is induced without use of fans and/or pumps such that efficiency of power usage is increased.

6. The passive fluid cooling system of claim 1, wherein the plurality of fluid cooling channels have one of a finned shape, a radial disc shape, a fractal design, a rectangular shape, a racetrack shape, a round shape, a flat channel shape and combinations thereof.

7. The passive fluid cooling system of claim 1, wherein the fluid is thermally conductive and electrically insulating.

8. The passive fluid cooling system of claim 7, wherein the fluid has electrically insulating properties to ensure that the fluid can safely contact energized electronic components.

9. The passive fluid cooling system of claim 8, wherein the fluid does not damage electronic components.

10. A passive cooling apparatus comprising:
an immersion cooling tank including a volume of fluid; and
a plurality of fluid cooling channels attached to exterior sidewalls of the immersion cooling tank, wherein flow of the fluid through the plurality of fluid cooling channels positioned on the exterior sidewalls of the immersion cooling tank removes heat from the volume of fluid.

11. The passive cooling apparatus of claim 10, wherein the plurality of fluid cooling channels are attached to the immersion cooling tank at first and second portions of the immersion cooling tank, as a temperature of the fluid in the immersion cooling tank increases, a density of the fluid decreases causing less dense fluid to rise to a top of the immersion cooling tank and flow into the plurality of fluid cooling channels cooling the fluid and flow back into the immersion cooling tank at a bottom portion of the immersion cooling tank.

12. The passive cooling apparatus of claim 11, wherein the flow of the fluid through the plurality of fluid cooling channels decreases the temperature of the fluid providing a cooled fluid.

13. The passive cooling apparatus of claim 10, wherein the flow of the fluid through the plurality of cooling channels is induced without use of fans and/or pumps such that efficiency of power usage is increased.

14. The passive cooling apparatus of claim 10, wherein the plurality of fluid cooling channels have one of a finned shape, a radial disc shape, a fractal design, a rectangular shape, a racetrack shape, a round shape, a flat channel shape and combinations thereof.

15. The passive cooling apparatus of claim 10, wherein the fluid is thermally conductive and electrically insulating.

16. The passive cooling apparatus of claim 15, wherein the fluid has electrically insulating properties to ensure that the fluid can safely contact energized electronic components.

17. The passive cooling apparatus of claim 16, wherein the fluid does not damage electronic components.

18. An immersion cooling tank comprising:
a plurality of fluid cooling channels attached to exterior sidewalls of the immersion cooling tank,
wherein flow of a volume of fluid through the plurality of fluid cooling channels positioned on the exterior sidewalls of the immersion cooling tank removes heat from the fluid; and
wherein the tank includes built in features that guide less dense fluid into the plurality of fluid cooling channels.

19. The immersion cooling tank of claim 18, wherein the built in features comprise a portion of a top of the tank angling downward to facilitate entry of the fluid into the plurality of fluid cooling channels.

20. The immersion cooling tank of claim 18, wherein the built in features include baffles inside the tank to direct the flow of the fluid, the baffles being one of an integral part of the tank and installed separately.
